(19) United States
(12) Patent Application Publication
(10) Pub. No.: US 2003/0180462 A1
(43) Pub. Date: Sep. 25, 2003

(54) Planetary lift-off vapor deposition system

(75) Inventors: Ping Chang, Danville, CA (US); Gregg Wallace, Alamo, CA (US); Russell J. Hill, El Cerrito, CA (US); Cris Kroneberger, Fairfield, CA (US); P.A. Joel Smith, San Pablo, CA (US)

Correspondence Address: PARSONS HSUE & DE RUNTZ LLP, 655 MONTGOMERY STREET, SUITE 1800, SAN FRANCISCO, CA, 94111, US

(73) Assignee: TEMESCAL, A UNIT OF THE BOC GROUP, INC.

(21) Appl. No.: 10/102,351

(22) Filed: Mar. 19, 2002

(51) Int. Cl. C23C 16/00; B05D 3/12

(52) U.S. Cl. 427/255.28; 118/726; 118/712; 427/240

(57) ABSTRACT

A physical vapor deposition coating system to produce orthogonal lift-off coatings. The system incorporates multiple domes that rotate about the source centerline and about another axis of rotation in order to assure an even coating and to utilize a large percentage of a material evaporated from the source.

### CROSS REFERENCE TO RELATED APPLICATIONS

This application is related to U.S. Pat. No. 6,342,103 to Ramsay, entitled “Multiple Pocket Electron Beam Source,” which is hereby incorporated by this reference in its entirety. This application is also related to U.S. Pat. No. 6,287,385 to Kroneberger, entitled “Spring clip for sensitive substrates,” which is hereby incorporated by this reference in its entirety.

### BACKGROUND OF THE INVENTION

1. Field of the Invention

The present invention relates generally to semiconductor processing and optical coatings, and more specifically to physical vapor deposition onto substrates.

2. Related Art

Electron beam evaporation is commonly used to coat wafers with a thin metallic layer in a process known as metalization. Generally, in typical silicon wafer fabrication, the metallic layer deposited is then etched to form circuit traces of an integrated circuit. However, gallium arsenide (GaAs), indium phosphide (InP) and numerous alloys between the two and similar electro-optical materials are now typically utilized as a substrate for high frequency integrated circuits of cellular devices, and etching of gold to form circuit traces on a GaAs substrate does not work well.

Gold is often used as the conductor of integrated circuits because in addition to being highly conductive, as a passive metal, gold will not form a superficial oxide. Therefore, a high frequency current applied to a circuit trace made of gold can easily flow through the skin of the circuit trace because it is not a resistive oxide layer. This is the well known skin effect in the conduction of high frequency power. This is critical in order to reduce power consumption in high powered GaAs IC's common in cellular devices. There are two problems with depositing a gold layer directly upon a GaAs substrate. First, the gold will leach into the substrate. Second, the gold will not adequately adhere directly to the substrate. Therefore, in order to prevent the gold from leaching into the substrate, a diffusion barrier of palladium or platinum separates the gold from the GaAs. Additionally, an adhesion layer of titanium or chromium is deposited upon the GaAs substrate between the substrate and the diffusion barrier in order to make the gold, and the diffusion barrier adhere to the substrate. These barrier and adhesion layers must typically be very thin yet very uniform.

FIG. 1 illustrates a cross section of a circuit trace showing adhesion layer 104 upon GaAs substrate 102. Upon adhesion layer 104 is diffusion barrier 106 upon which is the gold 108 that forms the circuit traces. The gold circuit traces cannot be etched away from the GaAs substrate in a typical etching process as they can on a silicon substrate because the etchant would remove the adhesion layer and diffusion barrier thus freeing the circuit trace from the substrate, a clearly undesirable consequence.

Therefore, the gold circuit traces are typically made according to a “lift-off” process. In the lift-off process a photoresist pattern having a trench 110 is formed upon the GaAs substrate, as can be seen in FIG. 2. First an adhesion layer, followed by a diffusion barrier are deposited sequentially, and finally gold is then deposited upon the photoresist pattern such that a portion 108a is deposited upon diffusion barrier 106 above photoresist layer 112 and a portion 108b is deposited upon diffusion barrier 106 within trench 110 . The gold 108b that is directly deposited upon the diffusion barrier will form the circuit traces. Any gold 108a and adhesion layer 104 plus diffusion barrier 106 that are deposited upon the photoresist will “lift-off’ the substrate when the photoresist layer is dissolved, as long as it is not connected in any way to the circuit formed from gold portion 108b deposited within the trench 110. Therefore, it is of the utmost importance that the sidewalls of the trench not be coated so that gold portions 108a and 108b are not connected to each other. Any gold connecting the two portions, even fine metal filaments, would result in an improper lift-off and defective circuit formation.

Thus, a source 120 of metal to be deposited must achieve a trajectory as close to 90 degrees with respect to the substrate surface as possible in order not to coat the sidewalls of trench 110. This is referred to as orthogonal deposition and the optimal resultant coating is referred to as a “lift-off” coating or as zero step coverage. A commonly used method of physical vapor deposition in lift-off processes is electron beam evaporation. In practical applications where multiple wafers must be precisely coated by a single source, this requires complex machinery with specific setups for specific power levels and materials.

One prior setup is illustrated in FIG. 3. Source 120 is located at the center of a sphere 130 having a radius R. The sphere is shown to illustrate that the lift-off dome has a dome spherical radius R such that all points on lift-off dome 124 are equidistant from source 120. At the top portion of the sphere is lift-off dome 124 that has multiple holes for holding wafers or other substrates to be coated. Lift-off dome 124 rotates around the source center line 132. One wafer 122 is illustrated on lift-off dome 124. Although all points on the lift-off dome are equidistant from the source, the source to substrate distance is not constant because each wafer is not arced, but flat. However, the difference is substantially negligible for the purposes of this application, and thus the source to substrate distance can be said to equal the dome spherical radius R.

In order to coat the wafers on lift-off dome 124, for example wafer 122, source 120 is heated by an electron beam (not shown) and the coating material is evaporated in a straight line towards wafers held within openings of lift-off dome 124. The vapor is not uniform and the distribution of the vapor varies with the power supplied to the electron beam, and also with the material to be evaporated. The vapor vector field is often described as a vapor cloud. If the lift-off dome and the wafers on the dome were stationary, the variations in the cloud would result in a very unevenly distributed coating upon the surfaces of each wafer. Rotation of the dome about source center line 132 substantially reduces the unevenness by averaging the variation in a circular path around the center line 132. However, the magnitude of the vapor vector field is much greater at the center line and tapers off as the distance on the dome from the center line increases as can be seen in FIG. 4. The thickness of the coating deposited is directly proportional to the magnitude of the vector field, and the thickness is also proportional to the distance on the dome from the center line or axis of rotation. FIG. 4 is a graph of the thickness distribution over different distances r from the centerline 132. The thickness of the coating deposited can be mathematically modeled according to the following relation:

$${T}_{r} α \frac{{cos}^{N} ( θ )}{{R}^{2}} ,$$

where Tᵣ is the thickness at point r, R is the dome spherical radius, N is a characteristic number for each power and material being vaporized, and θ is the angle from source centerline 132 to point r.

In order to reduce the thickness of the coating deposited nearest to the source center line 132, a stationary uniformity mask 126 is fixed between the source and the dome and has a width that tapers off with increasing radius. Thus, as lift off dome 124 rotates uniformity mask 126 blocks a larger portion of the vapor near the centerline (as θ approaches zero) than far from the centerline (as θ approaches ninety degrees). Because the vapor vector field varies for each different coating material and power level of the electron beam, a unique uniformity mask must be custom tailored not only for each coating material but for each given power level for each material. Changing the uniformity masks requires stopping the coating process and thus results in downtime of the coater. In order to deposit the multiple different metallic layers needed to make the circuit traces upon a GaAs wafer, at least 3 different uniformity masks would be needed to deposit the gold layer 108, adhesion layer 104 and diffusion barrier 108 seen in FIGS. 1 and 2. Furthermore, much of the evaporated metal is wasted because some is collected on the uniformity mask rather than on the wafer.

### SUMMARY OF THE INVENTION

Thus, there is a need for an electron beam coater capable of the orthogonal deposition necessary for lift-off applications that does not require a uniformity mask to evenly deposit a number of different coatings on multiple wafers simultaneously. Additionally, one that is less sensitive to process variations such as evaporant material, power level, beam position, and the like.

The planetary lift-off deposition system and method of the present invention deposits a uniform “lift-off” coating on a large amount of wafers in a short period of time. In comparison with prior vapor deposition devices and methods, the system and method of the present invention utilize a greater percentage of the vaporized material, do not require that any components be changed when vaporizing different materials, and reliably and consistently deposits a more uniform and precise coating.

In the preferred embodiment, the vapor deposition device utilizes dome shaped wafer holders positioned such that each point of a first face of the dome is equidistant from a source material to be evaporated. A rotating structure holding the dome shaped wafer holders rotates about a central axis passing through the source. The dome shaped wafer holders rotate about axes that passes through the center of the dome and the source thus eliminating the need for the uniformity mask. Although in the preferred embodiment illustrated, a dome shaped wafer holder is described, in other embodiments a support structure can locate the wafers such that the center of each wafer is equidistant from the source without the dome shaped carrier.

### BRIEF DESCRIPTION OF THE FIGURES.

FIG. 1 is a cross section of a prior art circuit trace on a GaAs substrate.

FIG. 2 is a cross section of a prior art lift-off deposition circuit trace.

FIG. 3 is an illustration of a prior art lift-off deposition system.

FIG. 4 is a graph of coating thickness as a function of horizontal distance from the source centerline.

FIG. 5 is a top view of planetary lift-off system 200.

FIG. 6 is a cross section of planetary lift-off system 200.

FIG. 7 is an enlarged section of planetary lift-off system 200.

FIG. 8 is a graph of coating distribution achieved with planetary lift-off system 200 in comparison to a coating made with a prior art system.

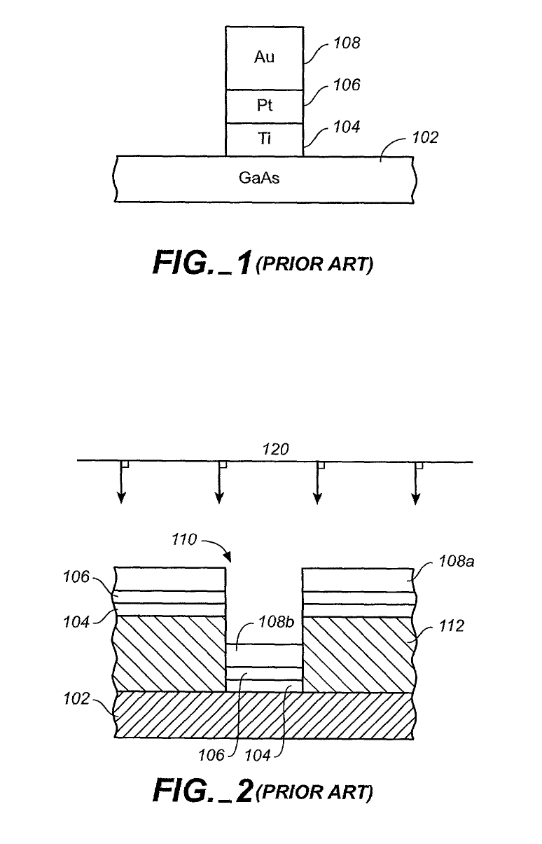

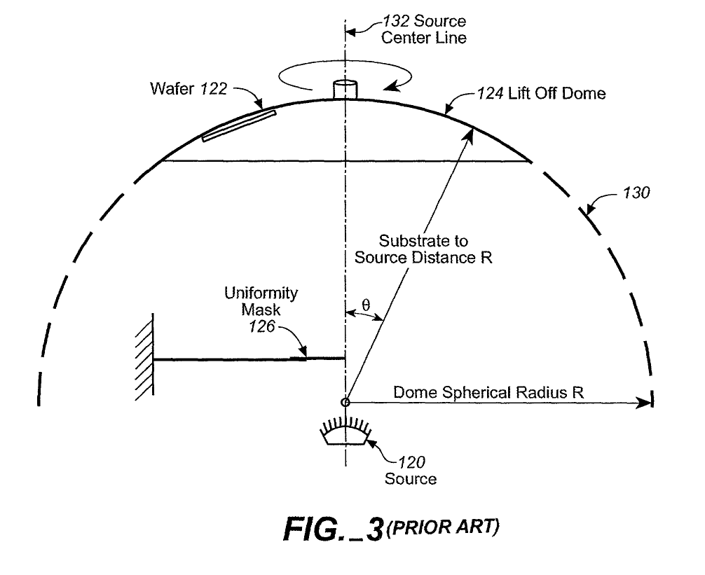

### DETAILED DESCRIPTION OF THE INVENTION

The planetary lift-off deposition system and method of the present invention deposits a uniform “lift-off” coating on a large amount of wafers in a short period of time. In comparison with prior vapor deposition devices and methods, the system and method of the present invention utilizes a greater percentage of the vaporized material, does not require any uniformity mask, does not require that any components be changed when vaporizing different materials, and reliably and consistently deposits a more uniform and precise coating. Finally, it is less sensitive to process variations than prior designs.

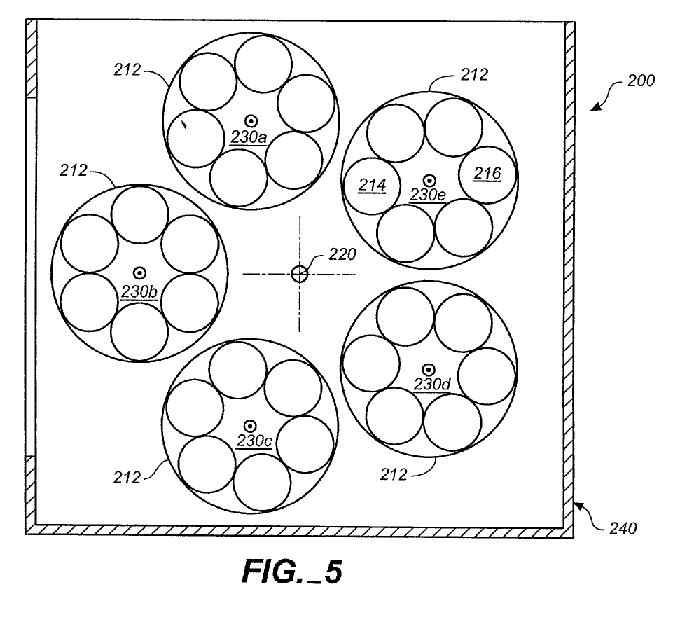

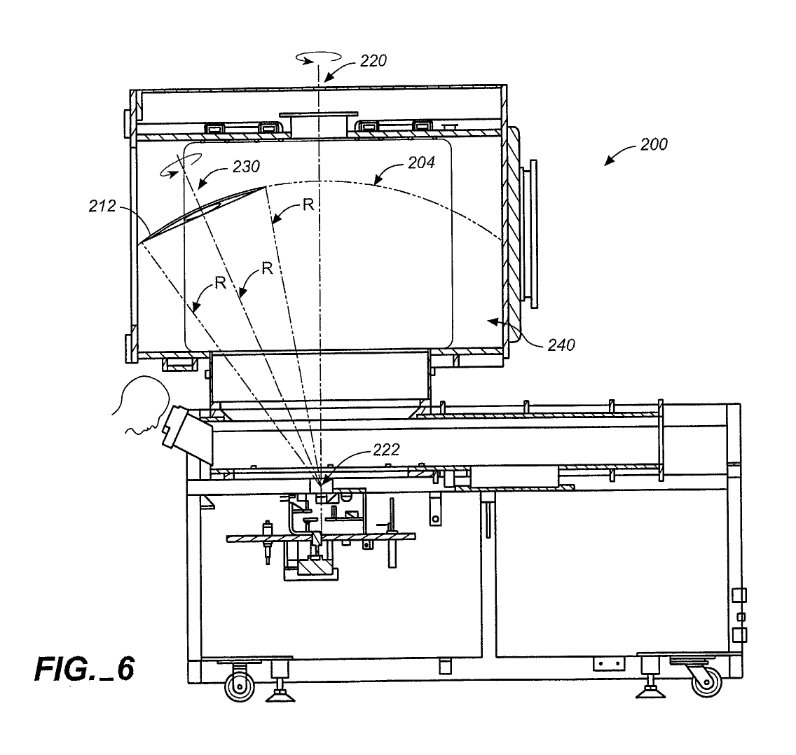

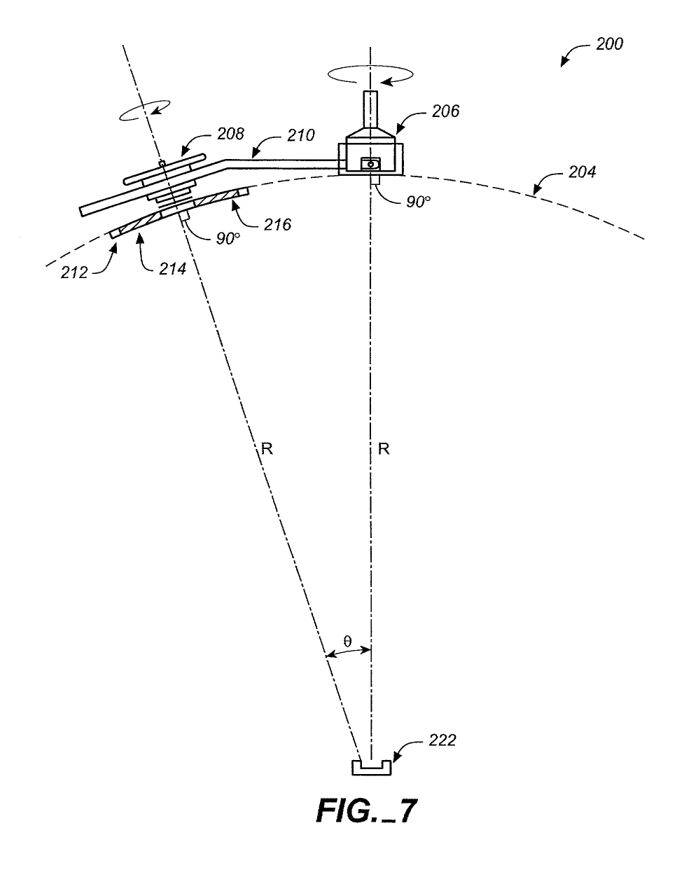

FIGS. 5-7 illustrate a planetary lift-off deposition system 200. FIG. 5 is a top view, FIG. 6 is a cross section, and FIG. 7 is an enlarged cross section of planetary lift-off deposition system (“PLDS”) 200. The invention will now be described with reference to the figures.

Electron beam vapor deposition generally occurs in a vacuum and thus, as seen in FIGS. 5 and 6, lift-off domes 212 are within a sealed vacuum chamber 240. PLDS 200 ranges in size and has a radius R anywhere from about 17.5 to 54 inches or more. The number and configuration of the domes 212 also varies depending on the application and wafer size, and can be anywhere from one to seven. Preferably three to six lift-off domes are arranged around centerline axis 220 positioned at the centerline of source 222. In the preferred embodiment used to illustrate the invention, five domes 212, each carrying six six-inch wafers, rotate about centerline axis 220 so that 30 wafers can be coated simultaneously. Each lift-off dome also rotates about dome axes 230—each dome has its own axis 230 a, b, c, d, e respectively. If smaller wafers are to be coated, the number that can be simultaneously coated increases, and vice versa. The lift-off dome is the preferred way of holding the wafers in position, but it is only one way. Other ways are within the scope of this invention. For example, a support frame or structure with one or more arms may hold the wafers in similar positions without having a dome shape. Many different configurations of structures can be constructed by one skilled in the art to individually position, interconnect, orient, and rotate the wafers according to the invention.

Two wafers 214 and 216 are shown within one of the lift-off domes 212. PLDS 200 can be thought of as a planetary system wherein each lift-off dome 212 is like a planet rotating about its own axis 230 as well as rotating about a centerline axis 220 (the sun). For clarity, the support frame 210 that locates the lift-off domes 212 in the proper position and controls the rotation of the domes about both centerline axis 220 and dome axes 230 is not shown in FIGS. 5 and 6 but can be seen in FIG. 7. One of the lift-off domes 212 seen in FIG. 5 is shown within chamber 240 in FIG. 6.

Lift-off domes 212 are constant radius domes such that any point on the surface of the domes is equidistant from source 222. Lift-off domes 212 are part of a sphere 204, at the center of which is located source 222. A portion of sphere 204, can be seen in FIGS. 6 and 7. Sphere 204 is theoretical and is only shown to make it clear that the lift-off domes have a constant radius R, the radius of sphere 204, and that source 222 is approximately equidistant from all points on the surface of domes 212 facing source 222. The source 222 contains a material to be evaporated by an electron beam. Material evaporated from source 222 will, generally speaking, travel outward from the source in a straight line along a radius R towards the domes 212, and thus the material will coat the domes 212 orthogonally, i.e. the trajectory of the material is normal to the surface of the domes 212 because the source 222 is located at the center of the sphere 204 of which domes 212 are a part. The source contains multiple pockets. Each pocket can hold a different material to be evaporated, and in order to evaporate and deposit multiple coatings, each pocket is rotated into the proper position to be evaporated by the electron beam. For more information please refer to U.S. Pat. No. 6,342,103 to Ramsay, entitled “Multiple Pocket Electron Beam Source” which is hereby incorporated by this reference in its entirety.

Referring to FIG. 7, one of the lift-off domes 212 is shown. For simplicity and clarity of illustration, only one lift-off dome 212 is shown, although lift-off deposition system 200 incorporates multiple domes 212, each of which holds multiple wafers. Lift-off domes 212 rotate about dome axes 230 that are aligned with source 222. Dome axes 230 are radii of the theoretical sphere 204 of which dome 212 is a part, and θ, the angle from axis 220 to axes 230 is equal for all axes 230a-e (or however many dome axes there may be).

Domes 212 rotate about dome axes 230. Space frame 210 positions lift-off domes 210 along sphere 204. Only a portion of space frame 210 can be seen in the cross section of FIG. 7. Space frame 210 rotates about axis 220 and also provides for the rotation of lift-off domes 212 about axes 230. Space frame 210 can be made of many materials well known to those skilled in the art, but is preferably made of a material such as stainless steel that is corrosion resistant and will give off a minimum amount of outgassing that may contaminate the vapor deposited coating. Any number of mechanisms including motors, gears, shafts, pulleys and other well known drive mechanisms can be used to provide for the rotation about the multiple axis. One such mechanism uses a stainless steel spring used as a pulley between spindle 206 and pulley 208. Alternatively, individual motors, flexible shafts, or a system of interconnected gears and motors can provide the planetary rotation. Each one or two rows of the wafers within domes 212 are equidistant from the axis of rotation 230. At the axes of rotation 230, domes 212 are normal to the axes 230. Wafers 214 and 216 are shown in this cross section of deposition system 200. As the distance along any of the wafers, for instance 214 or 216 increases from the centerline, a negligible deviation from orthogonal deposition occurs because the wafers are not arced, but flat. However, this deviation is quite minimal and does not significantly affect the lift-off properties of the coating, when R is chosen correctly for the wafer diameter of interest. For more information please refer to a paper hereby incorporated by reference entitled, “Improved Evaporation Deposition for Lift-Off Patterning,” by R. J. Hill, Society of Vacuum Coaters, 32^{nd} Annual Technical Conference Proceedings p.278, 1989.

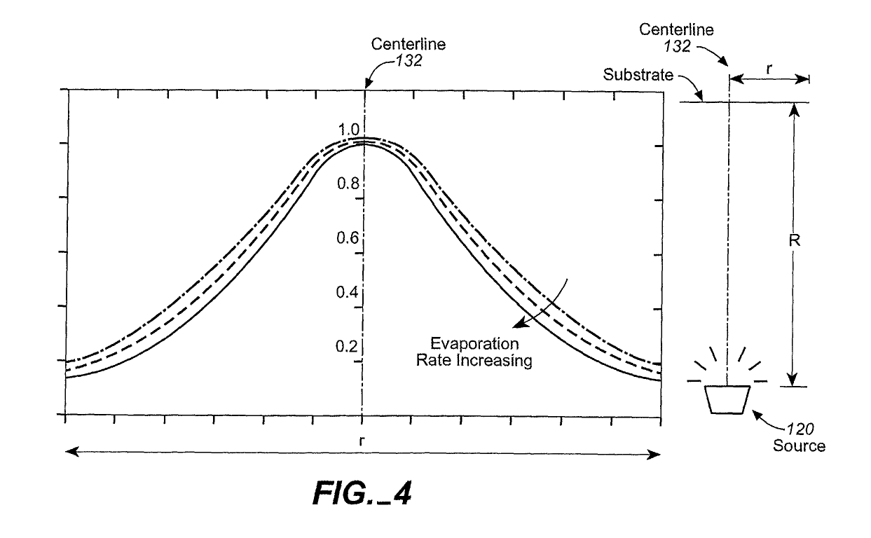

As discussed in the background with regard to FIG. 4, the thickness of the coating is greatest just above the source and diminishes as the distance r from axis of rotation 220 (the centerline) increases. The diminution of the coating with increasing distance r is averaged out by the rotation of the wafer holders about axes 230. Because the wafers rotate about the axes 230, a given point on a wafer is exposed to a higher deposition rate resulting in a thick coating when nearest to centerline axis 220 (source center line) and to an increasingly thinner coating as the distance from centerline axis 220 (source center line) increases. In one planetary revolution or cycle any point on any wafer is thus coated with the same thickness as any other point on any of the wafers, and therefore each of the wafers are evenly coated. This evenly deposited coating is achieved without the use of a uniformity mask that is typical in prior art lift-off deposition systems.

In prior deposition systems, the coating was evenly deposited by blocking the thicker portion of the coating with the uniformity mask. As can be seen in FIG. 4 the thickness utilized near the edge of the curve can be as little as 20% as that deposited near the center, but is typically 60-90%. A minimal thickness point on the curve governed the final thickness to be deposited upon the wafer, as the thicker portion of the curve was selectively blocked from arriving at the wafer surface by the uniformity mask. Thus, a large portion of the material to be deposited was wasted because it ended up coating the mask rather than the wafers. This was thus an inefficient and costly system. With the present invention, a much higher percentage of the material that is evaporated is actually deposited on the wafer, because no material must be blocked in order to achieve a uniform coating.

Typically, gold is used to form the circuit traces in GaAs applications as discussed earlier. What follows is an example to illustrate the amount of money saved during a year of usage of the planetary lift-off deposition system (“PLDS”) of the present invention vs. a prior existing design (“Prior Art”) incorporating a uniformity mask.

TABLE 1
Amount of Gold Consumed to Deposit 7000 Å Coating.

| Characteristics for 1 run | PRIOR ART | PLDS |
|---|---|---|
| Coating thickness sought, Å | 7000 | 7000 |
| Minimum thickness, Å | 7000 | 7000 |
| Maximum thickness, Å | 10387 | 7383 |
| Average thickness, Å | 9095 | 7251 |
| Coating uniformity, % | 18.62 | 2.64 |
| Total evaporated, grams | 36.21 | 32.63 |

As can be seen in Table 1, the PLDS exemplifying the present invention uses about 3.58 less grams per run and is approximately 9.9% more efficient than the prior art systems. Assuming a typical shift is 1880 hours per year (47 weeks @ 40 hrs per week) and there are three shifts per week, a deposition system (PLDS or the prior art system) can be used 5640 hours per year. In each hour there are two runs. Factoring in a downtime of 10% for each machine, and a yield of 98%, the present invention saves roughly 35,500 grams of gold per year, as can be seen in Table 2. Assuming the cost of gold is $280 per Troy ounce, the PLDS system will save an operator over $320,000 per year.

TABLE 2
Cost of Operation per Year.

| | | Grams evaporated | Grams per | |
|---|---|---|---|---|
| | Runs | per run to | year (10% | Cost per year |
| | per | 7000 Å | downtime and | ($280 per |
| | year | coating | 98% yield) | Troy Oz.) |
| PLDS | 11,280 | 32.63 | 324,634 | $2,922,750 |
| PRIOR ART | 11,280 | 36.21 | 360,252 | $3,243,426 |

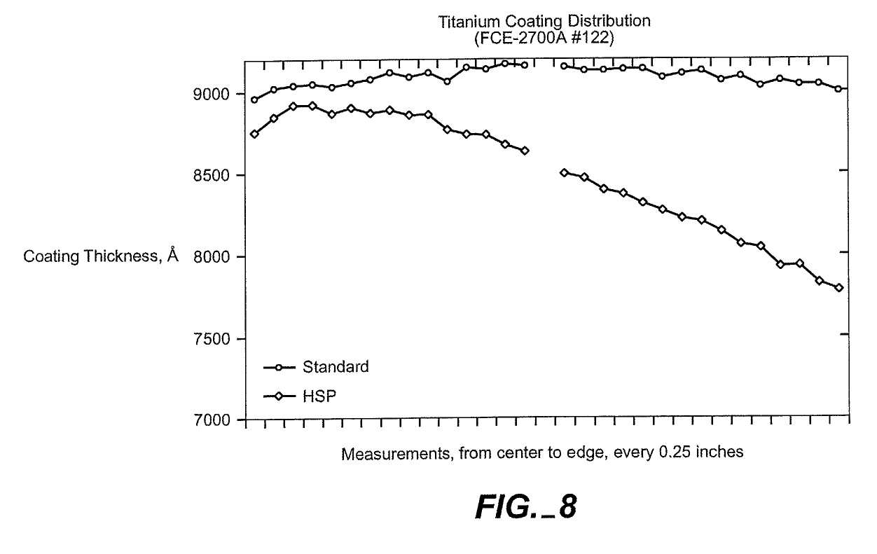

FIG. 8 illustrates the uniformity of the coating deposited using PLDS vs. that deposited with a prior art system. Note that in depositing a 9000 Å coating with the PLDS, the coating deposited is within about 1.2% of the target across the surface of the wafer whereas the coating deposited with the prior art is thinner at the edge of the wafer by about 6.8%. Therefore the present invention is not only more efficient but also deposits a more uniform and precise coating than prior art systems.

While particular embodiments of the present invention and their advantages have been shown and described, it should be understood that various changes, substitutions, and alterations can be made therein without departing from the spirit and scope of the invention as defined by the appended claims. For example, any device or method of positioning and rotating the domes in the proper position is within the scope of the invention as defined by the appended claims.

1. A device for depositing a coating orthogonal to the surface of one or more wafers and onto a photoresist pattern that may be present upon the surface of the one or more wafers comprising:
one or more domes having a constant radius about a centerpoint, the one or more domes rotating about a first axis that runs through the centerpoint;
a source material positioned at the centerpoint;
one or more wafers positioned within each of the one or more domes, wherein each dome and the one or more wafers rotate about a second axis that runs through the centerpoint and through the center of each dome such that a wafer in the one or more wafer holders is rotating about both the first and second axis simultaneously and such that the coating is deposited upon the surface and photoresist pattern that may be present upon the one or more wafers.

2. The device of claim 1 wherein the coating deposited is substantially uniform and orthogonal to the surface and photoresist pattern of the one or more wafers without the use of a uniformity mask positioned between the source and the one or more wafers.

3. The device of claim 1 wherein the first axis is between the one or more domes and the second axis is between the one or more wafers of each dome.

4. The device of claim 1 further comprising a support structure that positions and rotates the domes about the first axis.

5. The device of claim 4 wherein the support structure positions the domes such that the arc of the domes is aligned with the circumference of a sphere having its center at the centerpoint.

6. The device of claim 4 wherein the support structure comprises a drive system that rotates the one or more domes about their respective second axis.

7. A vapor deposition device comprising:
a source of material to be vaporized;
dome shaped wafer holders positioned such that each point of a first face of the wafer holders is equidistant from the source, each wafer holder having a dome axis that passes through the center of the wafer holder and the source, the dome shaped wafer holders rotating one or more wafers within the holders about the dome axis; and
a rotating structure holding the dome shaped wafer holders and rotating the holders about a centerline axis of the source.

8. The vapor deposition device of claim 7 wherein the material vaporized travels along a trajectory normal to each point of the first face of the dome shaped wafer holders and deposits a coating on the wafers substantially normal to the surface of the wafers.

9. The vapor deposition device of claim 8 wherein the material vaporized produces a coating upon the surface of the wafer or a photoresist pattern on the surface of the wafer thereby allowing lift-off of the coating deposited on the photoresist pattern on the surface of the wafer.

10. The vapor deposition device of claim 7 wherein the rotating structure comprises one or more pulleys, gears, shafts, or motors for rotating the dome shaped wafer holders.

11. The vapor deposition device of claim 10 wherein the vapor deposition device further comprises a motor that rotates the rotating structure.

12. A method for producing a lift-off coating on a wafer comprising:
evaporating material from a source;
rotating a wafer within a wafer holder about a first axis that passes through the center of the wafer holder and the source, the wafer holder positioned such that a center point of each wafer is equidistant from the source; and
rotating the wafer holder about a second axis that passes through the source.

13. The method of claim 12 wherein the material vaporized travels along a trajectory normal to the center point of each wafer and deposits a coating on the wafers substantially normal to the surface of the wafers.

14. The method of claim 12 wherein the material vaporized produces a coating upon the surface of the wafer or a surface parallel to the surface to the wafer thereby allowing lift-off of the coating deposited on a surface parallel to the surface of the wafer.

15. The method of claim 12 wherein rotating the wafer and rotating the wafer holder occur simultaneously.

16. A vapor deposition device comprising:
a source of material to be vaporized;
a means for positioning wafers such that the center of each wafer is equidistant from the source, the means for positioning the wafers rotating the wafers about a first axis that passes through the source;
a means for rotating the means for positioning wafers about a second axis that passes through the source.

17. The vapor deposition device of claim 16 wherein the means for positioning and the means for rotating rotate the wafers about the first and second axes simultaneously thereby moving each wafer on a similar path through a vapor cloud.
